(19) United States
(12) Patent Application Publication
(10) Pub. No.: US 2007/0231710 A1
(43) Pub. Date: Oct. 4, 2007

(54) Method and system for forming a photomask pattern

(75) Inventors: Thomas J. Aton, Dallas, TX (US); Robert A. Soper, Plano, TX (US)

Correspondence Address: TEXAS INSTRUMENTS INCORPORATED, P O BOX 655474, M/S 3999, DALLAS, TX, 75265, US

(73) Assignee: Texas Instruments Incorporated.

(21) Appl. No.: 11/392,655

(22) Filed: Mar. 30, 2006

(51) Int. Cl. G03C 5/00; G06F 17/50; G03F 1/00

(52) U.S. Cl. 430/5; 430/30; 716/19; 430/311

(57) ABSTRACT

The present application is directed to methods of forming a photomask pattern for writing a photomask. In one embodiment, a method of the present application comprises providing a first pattern for forming an integrated circuit feature, adjusting the first pattern to form a second pattern that accounts for transition region effects in the first pattern, and correcting the second pattern for proximity effects to form the photomask pattern. Systems for forming photomasks according to methods of the present application are also disclosed.

### DESCRIPTION OF THE DISCLOSURE

1. Field of the Disclosure

The present application relates generally to the field of photolithography, and more specifically to methods and systems for preparing photomasks.

2. Background of the Disclosure

Conventional optical projection lithography has been the standard silicon patterning technology for the past 20 years. It is an economical process due to its inherently high throughput, thereby providing a desirable low cost per part or die produced. A considerable infrastructure (including steppers, photomasks, resists, metrology, etc.) has been built up around this technology.

In this process, a photomask, or “reticle”, includes a semiconductor circuit layout pattern typically formed of opaque chrome, on a transparent glass (typically SiO₂) substrate. A stepper includes a light source and optics that project light coming through the photomask to image the circuit pattern, typically with a 4× to 5× reduction factor, on a photo-resist film formed on a wafer. The term “chrome” refers to an opaque masking material that is typically but not always comprised of chrome. The transmission of the opaque material may also vary such as in the case of an attenuating phase shift mask.

As the critical dimensions of integrated circuits continue to decrease, there is a need to pattern smaller and smaller features. Modern photolithographic systems often employ light in the imaging process which has a larger wavelength than the critical dimensions of the device features being formed on the integrated circuits. When critical dimensions are printed at less than or equal to the wavelength of light being used, the wave properties of the light become a dominant property of the lithography. In general, these wave properties are seen as being a limiting factor in lithography. There are, however, techniques for extending optical lithography beyond the range of conventional imaging.

One such technique is known as optical proximity correction. In this method, a computer program is often used to simulate a 2-D aerial image that is formed for a particular photomask feature or group of features. Based on this simulated aerial image, the reticle pattern can be altered and then simulated again to determine if the altered pattern has improved the 2-D aerial image. This process can be repeated until a desired 2-D aerial image is achieved. The features added to a reticle pattern based on this procedure are called optical proximity correction features.

However, it has been found that increasing density of circuit devices can result in instances where the critical dimensions of some devices, such as the gate length of a MOS transistor, can be difficult to accurately pattern, partly due to limitations of the optical proximity correction process. This can cause problems in integrated circuit fabrication. For example, in the case where a gate length is formed shorter than design tolerances permit, increased leakage current and decreased yields can result.

### SUMMARY OF THE DISCLOSURE

In accordance with the disclosure, an embodiment of the present application is directed to a method of forming a photomask pattern for writing a photomask. The method comprises providing a first pattern for forming an integrated circuit feature; adjusting the first pattern to form a second pattern that accounts for transition region effects in the first pattern; and correcting the second pattern for proximity effects to form the photomask pattern.

Another embodiment of the present application is directed to a system for generating a photomask pattern. The system comprises a database operable to store data describing an integrated circuit feature having a target dimension. The system also comprises a module coupled to the database, wherein the module comprises a set of instructions in computer readable form. The instructions of the module are operable to determine pattern adjustments to a first pattern for forming the integrated circuit feature to account for transition region effects in the first pattern, and generate output representing the pattern adjustments.

Another embodiment of the present application is directed to a method of forming a photomask pattern for an integrated circuit feature having a gate length that is designed to be formed within a desired tolerance range. The method comprises providing a first pattern that comprises a region for patterning the gate length and a transition region, the transition region comprising a change in dimension to achieve the gate length. The transition region of the first pattern is adjusted to form a second pattern that provides a more gradual change in dimension to achieve the gate length than the transition region of the first pattern. The second pattern is corrected for proximity effects to form the photomask pattern.

Another embodiment of the present application is directed to a photomask comprising a pattern for forming an integrated circuit feature having a target dimension that is designed to be formed within a desired tolerance range. The photomask is made by a method comprising providing a first pattern that comprises a region for patterning the target dimension and a transition region, the transition region comprising a change in dimension to achieve the target dimension. The transition region of the first pattern is adjusted to form a second pattern that provides a more gradual change in dimension to achieve the target dimension than the transition region of the first pattern. The second pattern is corrected for proximity effects to form the photomask pattern.

Additional objects and advantages of the disclosure will be set forth in part in the description which follows, and can be learned by practice of the disclosure. The objects and advantages of the disclosure will be realized and attained by means of the elements and combinations particularly pointed out in the appended claims.

It is to be understood that both the foregoing general description and the following detailed description are exemplary and explanatory only and are not restrictive of the disclosure, as claimed.

The accompanying drawings, which are incorporated in and constitute a part of this specification, illustrate several embodiments of the disclosure and, together with the description, serve to explain the principles of the disclosure.

### BRIEF DESCRIPTION OF THE DRAWINGS

FIG. 1 illustrates a flow diagram of a process for making a photomask used for patterning an integrated circuit feature, according to an embodiment of the present application.

FIG. 2A illustrates one embodiment of a photomask pattern generated to pattern an integrated circuit feature, according to an embodiment of the present application.

FIG. 2B illustrates one technique for adjusting transition regions of the photomask pattern of FIG. 2A to form a second pattern, according to an embodiment of the present application.

FIG. 3A illustrates certain problems that can arise when proximity correction is carried out on a target pattern.

FIG. 3B illustrates the results of carrying out proximity correction on a portion of the second target pattern of FIG. 2B, according to an embodiment of the present application.

FIG. 4 illustrates one embodiment of a trim pattern for patterning an integrated circuit feature, according to an embodiment of the present application.

FIG. 5 illustrates a system for forming a photomask pattern, according to an embodiment of the present application.

### DESCRIPTION OF THE EMBODIMENTS

Reference will now be made in detail to various exemplary embodiments of the present application, examples of which are illustrated in the accompanying drawings. Wherever possible, the same reference numbers will be used throughout the drawings to refer to the same or like parts.

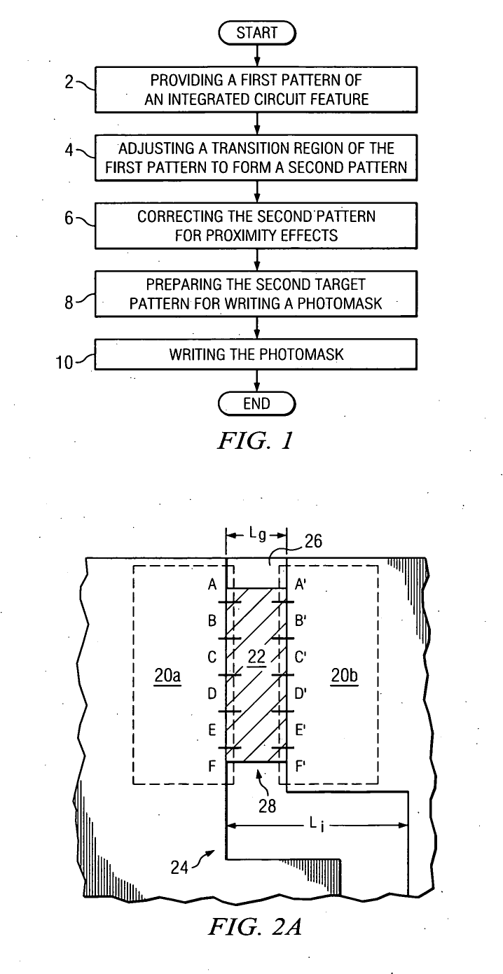

FIG. 1 illustrates a flow diagram of one embodiment of a process for making a photomask used for patterning an integrated circuit device. The process may be used to form any suitable type of photomask, such as binary masks, embedded attenuated phase shift masks, and alternating phase shift masks.

As shown in block 2 of the FIG. 1 embodiment, a first pattern for forming a photomask of an integrated circuit feature is provided. The process of providing the first pattern may comprise, for example, generating a photomask pattern from a design database containing data describing at least a portion of the integrated circuit design. Methods for generating photomask patterns from design data are well known in the art, and any suitable method may be employed. In an embodiment, the photomask patterns are drawn using software programs designed to read data from the design database and prepare appropriate patterns for forming the photomasks used to make the integrated circuit designs described in the database. One example of a suitable software program is the PROTEUS software package available from SYNOPSYS, Inc.

As illustrated in block 4 of the FIG. 1 embodiment, a second pattern is formed by adjusting a transition region of the first pattern. This adjustment of the first pattern allows correction of the second pattern for proximity effects during the process of block 6, so that the target dimension of the integrated circuit feature can be formed within desired tolerance ranges, or at least can avoid being formed shorter than design tolerances permit, as will be discussed in greater detail below.

The shape of the photomask pattern formed in block 4 will generally reflect a target pattern, which is the desired shape of the pattern to be formed on the wafer. However, the shape of the final pattern formed on the photomask may sometimes differ from the target pattern to take into account proximity effects, such as, for example, optical diffraction effects, etch effects, and device density effects. To account for such proximity effects on patterning, photomask patterns may be adjusted using proximity correction techniques, as indicated in blocks 6 of the embodiment of FIG. 1. Any suitable technique for correcting for proximity effects may be employed. Examples of suitable proximity correction techniques are disclosed in U.S. Pat. No. 6,764,795, issued on Jul. 20, 2004 to Aton et al., the disclosure of which techniques is herein incorporated by reference in its entirety.

After correction of the second pattern for proximity effects, the photomask pattern data is prepared for manufacturing, or writing, the photomask, as shown in block 8. For example, the photomask pattern data may be fractured, which puts the data in a form which is compatible with the photomask writing process. The data fracture process may be accomplished by any suitable software program. Suitable software programs for photomask data fracturing are well known in the art, such as, for example CATS, available from SYNOPSYS, Inc.

The photomask data is then used to write the photomasks, as shown in block 10 of FIG. 1. Any suitable technique for writing the photomask may be used. Suitable techniques for writing photomasks are well known in the art.

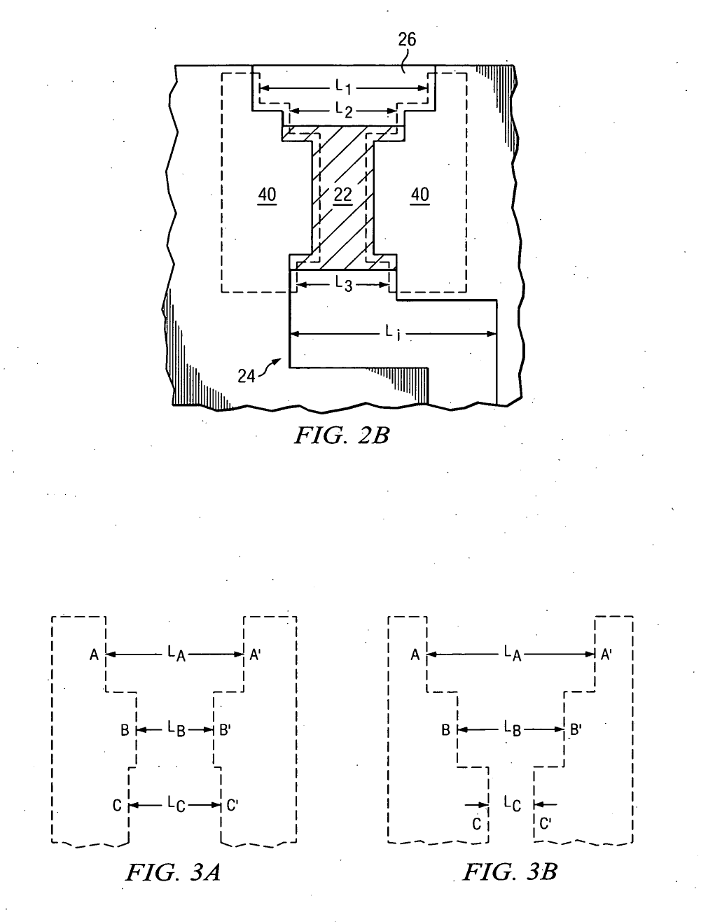

An exemplary embodiment of the process of FIG. 1 will now be described with reference to FIGS. 2A and 2B. FIG. 2A illustrates one embodiment of a photomask pattern 20 generated to pattern an integrated circuit feature 22. In the present example, integrated circuit feature 22, represented by the hatched region of device 24, is a gate region of a CMOS transistor. However, integrated circuit feature 22 may be any suitable feature desired to be patterned, such as gate regions of other types of MOS transistors, interconnects, diffusion regions of transistors, contact regions, via regions, and implant regions.

Integrated circuit feature 22 has a target dimension, L_{g}, in this case a gate length, which is designed to be formed within a desired range of design tolerances. The desired tolerance range may depend on various parameters, such as the type of device being formed, the desired properties of the device, and device density on the wafer. For certain target dimensions, such as gate lengths, design tolerances can be very high, such as for example, within about 1 nm to about 2 nm of the preselected gate length, L_{g}.

Device 24 further comprises transition regions 26 and 28, formed on either side of the integrated circuit feature 22. In the illustrated embodiment, transition region 26 may be a gate end, while transition region 28 may be a portion of an interconnect proximate integrated circuit feature 22. Transition regions 26 and 28 of device 24 comprise a change in dimension proximate to the integrated circuit feature 22 to achieve the target dimension. For example, because transition region 26 is proximate to an end of device 24, achieving the target dimension requires transitioning from a region where no pattern exists, to integrated circuit feature 22 having target dimension, L_{g}. Similarly for transition region 28, achieving the target dimension requires transitioning from the interconnect, having a length, Li, which is relatively large, to the integrated circuit feature 22 having target dimension, L_{g}, which is relatively small.

In the illustrated embodiment, photomask pattern 20 may comprise phase blocks 20a and 20b of a phase shift mask, where phase blocks 20a and 20b have different phase shifts. Such phase shift masks are well known in the art. While the embodiment of FIGS. 2A and 2B is directed to a phase shift mask, the processes of the present application may be used to form any suitable type of photomask, such as binary masks and embedded attenuated phase shift masks, as discussed above.

In embodiments where positive photoresist is employed in the patterning process, photomask pattern 20 represents regions where the photomask is transparent to the imaging light, while the surrounding regions, including the integrated circuit feature 22 and transition regions 26 and 28, represent dark regions on the photomask that are opaque to the imaging light. While the illustrated embodiment is directed to a process employing positive photoresist patterns, one of ordinary skill in the art would readily understand that the principles of the present application can be applied to processes employing negative photoresist, as well.

Phase blocks 20a and 20b are positioned on either side of integrated circuit feature 22, the distance between phase blocks 20a and 20b determining the target dimension, L_{g}. However, as discussed above, the shape of the final patterns formed on the photomasks may sometimes differ from the target pattern to take into account such things as proximity effects. To account for these effects on patterning, photomask pattern 20 may be adjusted using proximity correction techniques, such as optical proximity correction, as indicated in blocks 6 of the embodiment of FIG. 1.

However, it has been discovered by the inventors of the present application that when proximity correction is carried out on a target pattern such as the one illustrated by phase blocks 20a and 20b, problems can arise during the proximity correction process that can result in improper patterning. In order to prevent or reduce these problems, the target pattern may be altered, as will be discussed in greater detail below.

In some embodiments of the present application, correcting a phase shift pattern may comprise dividing phase blocks of the phase pattern into a plurality of segments in order to determine proximity effects for each segment, as described, for example, in U.S. Pat. No. 6,764,795, issued on Jul. 20, 2004 to Aton et al. The disclosure of the '795 patent that is related to correcting phase patterns in this manner is herein incorporated by reference in its entirety, as described above.

FIG. 2A illustrates such an embodiment where phase block 20a is divided into segments A, B, C, D, E, and F and phase block 20b is divided segments A′, B′, C′, D′, E′ and F′. The segments provide target positions for target dimension, L_{g}. The individual segments can then be repositioned during the proximity correction process of block 6 to account for proximity effects in the regions of each segment in order to achieve the desired target dimension. The positioning of each segment is determined by modeling software that evaluates a set of parameters, including, for example, calculated light intensity values, for each segment.

Modeling software for calculating light intensity values is well known in the art. As would be appreciated by one of ordinary skill in the art, the modeled light intensity is not necessarily the same as the light intensity that will be realized during patterning of the photoresist due to modeling limitations. Furthermore, as is well known in the art, while the models can be dominated by light intensity effects, the models may also take into account other effects, such as etch proximity effects, resist chemistry effects and other empirical effects not easily classified. Accordingly, modeling the light intensity for computing proximity effects may take into account these additional modeling effects.

FIG. 3A illustrates certain problems that can arise when proximity correction is carried out on a target pattern such as the one illustrated by phase blocks 20a and 20b of FIG. 2A. In FIG. 3A, the segments of phase blocks 20a and 20b are positioned in an exemplary manner as they might be during a process of correcting for proximity effects for transition region 26 and an upper portion of integrated circuit feature 22. In the illustrated embodiment, the two end segments A and A′ define the transition region 26, as well as the end of integrated circuit feature 22. As illustrated in FIG. 3A, segments A and A′ are shifted a relatively large distance, L_{A}, apart, in order to account for certain transition region patterning effects near the transition region 26.

In some embodiments, these transition region effects may be partly due to the need to transition rapidly between pattern regions having different dimensions, which may cause a lack of control of the spatial response for forming the pattern, as will be explained in greater detail below. For example, in transition region 26 the pattern changes in a relatively short distance from no pattern at all to integrated circuit feature 22, which in this example is a fully realized gate. To begin the photoresist pattern within the distance of transition region 26 and achieve the target dimension, L_{g}, as quickly as possible, a relatively large dark space must be created by the photomask pattern, which results in segments A and A′ being positioned a relatively long distance apart. The transition region effects may also include such things as diffraction off the ends of the phase shift blocks 20a and 20b, as well as diffraction from device patterns proximate the transition region 26, which can also result in segments A and A′ being positioned farther apart.

To compensate for the large dark space created by the positioning of end segments A and A′, the modeling software may position the second set of segments B and B′ a distance, L_{B} apart, where L_{B} is relatively small compared to L_{A}, in an attempt to achieve the target dimension, L_{g}, for the portion of integrated circuit feature 22 defined by segments B and B′. However, the control of the spatial response of the lithographic system may be insufficient to allow the necessary adjustment to go abruptly from the large dark space defined by segments A and A′, to the much smaller dark space defined by segments B and B′, in such a short distance.

While not intending to be limited by theory, this lack of control of the spatial response in forming the resist pattern may be partly due to the limits of how sharply imaged photoresist patterns can change shape over very short distances and the fact that the phase block segments can only be so small compared to the wavelength of light in order to have any effect on diffraction, as well as other limits in the lithographic system. Whatever the reason, the lack of control of the spatial response can cause the segments in the transition region to oscillate around the target dimension, thus resulting in formation of a photoresist pattern that can be shorter in some segments and/or wider in other segments, than the target dimension, L_{g}. For example, in FIG. 3A, the positioning of segments A and A′ may overshoot the target dimension, resulting in the pattern being wider than L_{g}, while the positioning of the second set of segments B and B′ may undershoot the target dimension, resulting in a gate length that is less than design tolerances allow, before the desired target dimension is achieved by the positioning of segments C and C′. This overshoot and/or undershoot problem will often occur if the segments are targeted to follow the dimensions of the originally designed first pattern of the integrated circuit feature, similarly as illustrated in FIG. 2A.

A similar problem can result from the situation in FIG. 2A for the portion of the integrated circuit feature 22 proximate interconnect transition region 28. The abrupt change in pattern dimension when going from the width of the interconnect, Lᵢ, to the target gate length, L_{g}, can cause the proximity correction modeling software to undershoot and/or overshoot the target dimension due to similar “transition region effects” as described above. In the case of undershooting the target dimension, this can result in a patterned gate length that is less than the design tolerances allow.

Undershooting the target dimension can result in relatively serious problems. For example, formation of a gate length that is too short, even for a small segment of the gate region, can dramatically increase leakage current. Further, because the resist is often patterned at dimensions near the limits of the ability of the resist to form a pattern, imaging a pattern that is too short can result in failure of the resist to form the imaged pattern, which may result in the conductor forming the integrated circuit feature separating into two pieces and making the transistor a functional failure.

To avoid or reduce the problems discussed above, such as undershooting the target dimension, the transition regions of the first pattern may be adjusted to form a second pattern, as indicated in block 6 of FIG. 1. FIG. 2B illustrates one technique for adjusting transition regions 26 and 28 to form a second pattern 40 that is capable of being corrected for proximity effects so that the target dimension of the integrated circuit feature is maintained within desired tolerances, or is at least not formed shorter than design tolerances permit, thereby avoiding or reducing the undershoot problem.

In the embodiment of FIG. 2B, one or more of transition regions 26 and 28 of first pattern 20, shown in FIG. 2A, can be altered so that second pattern 40 includes a step down pattern that results in a more gradual transition for achieving the target dimensions than in the first pattern 20. The step down pattern comprises one or more increasingly narrow pattern regions to achieve the target dimension. As shown in FIG. 2B, the transition region 26, which may include an end portion of integrated circuit feature 22, is adjusted to form a step pattern where the uppermost region of phase blocks 20a and 20b are a distance L₁ apart, and then an adjacent lower stepped down region of phase blocks 20a and 20b are formed a distance L₂ apart, where L₁, is greater than L₂, and L₂ is greater than L_{g}.

The more gradual decrease in dimension of the step down pattern results in a more gradual decrease in the distance between the repositioned segments necessary to achieve the target dimension, L_{g}, during the subsequent process of correcting for proximity effects. This relatively gradual decrease can be seen in FIG. 3B, where segments A and A′ are positioned to achieve the L₁, target dimension, segments B and B′ are positioned to achieve the L₂ target dimension, and the C and C′ segments are positioned to achieve the L_{g} target dimension. The adjusted pattern 40 of FIG. 2B effectively retargets the segments so as to result in improved control of the spatial response during correction for proximity effects, thereby reducing oscillation in the positioning of the segments, as compared with the embodiment of FIG. 3A, and resulting in formation of the target dimension, L_{g}, within the allowed design tolerances.

Referring back to FIG. 1, the process of adjusting the transition region of the first pattern of block 4 may occur as a separate process between providing the first pattern of block 2 and correcting the second pattern of block 6. In other embodiments, the process of adjusting the transition region of the first pattern of block 4 may occur as an integrated process with either or both of the processes of providing the first pattern of block 2 and correcting the second pattern of block 6.

For example, in one embodiment, calculations performed during the process of block 6 for correcting proximity effects may be employed to determine the adjustments to the first pattern 20 to achieve second pattern 40. In this embodiment, the step down pattern in the transition region 26 of second pattern 40 can be effectively determined by performing light intensity calculations at multiple points along each segment in transition region 26 during the process of correcting for proximity effects. If it is determined that at any point along the segment A that the light intensity is above a threshold intensity necessary for formation of the photoresist, the entire segment can be repositioned out. This process may be repeated iteratively, until it is determined that the entire segment is below the threshold. In this manner, segments A, B, C, A′, B′ and C′in FIG. 3B may be effectively retargeted to produce a step down pattern that avoids forming portions of the integrated circuit feature to be shorter than design tolerances permit.

In other embodiments, the step down pattern of FIG. 2B may be determined experimentally to provide improved control of the spatial response during correction for proximity effects. In this embodiment, preselected values experimentally determined to reduce oscillation in the positioning of the segments may be employed for L₁ and L₂ in FIG. 2B, in order to avoid forming portions of the integrated circuit feature to be shorter than design tolerances permit.

In some embodiments, the adjusted transition regions of second pattern 40 may result in a portion of the integrated circuit feature 22 having a length that is greater than the design tolerances for target dimension, L_{g}. For example, because new targets L₁ and/or L₂ in the illustrated embodiment are greater than the target dimension, they may result in a portion of the gate region proximate the gate end being greater than design tolerances for L_{g}. However, this is generally considered to be an improvement over the overcorrection problem of FIG. 3A, where a portion of the gate region is formed to be less than design tolerances permit, because gate regions that are less than design tolerances permit can result in dramatic increases in leakage current and/or yield loss.

A pattern adjustment similar to the adjustment described above for transition region 26 can also be made for the portion of integrated circuit feature 22 proximate transition region 28, as illustrated in FIG. 2B. Rather than abruptly changing dimensions from Lᵢ to L_{g}, as in the first photomask pattern 20, the pattern 40 comprises a step down pattern where the lower most portion of phase blocks 20a and 20b are a distance L₃ apart, where Lᵢ is greater than L₃, and L₃ is greater than L_{g}. During the subsequent process of correcting for proximity effects, this step down pattern allows a more gradual decrease in the distance between segments to achieve the target dimension while avoiding or reducing the overcorrection problem described above.

The adjustments to first pattern 20 are not limited to the step down pattern illustrated in the embodiment of FIG. 2B. Any suitable pattern which may avoid or reduce the problem of lack of spatial control during correction of proximity effects, as described, above may be employed. For example, while FIG. 2B illustrates step down patterns with a single additional step of length L₂ in transition region 26, and a single additional step of length L₃ in transition region 28, transition regions with any number of steps are contemplated. For example, in other embodiments, two or more steps may be employed to gradually narrow the transition region to achieve the target dimension. In another embodiment, transition regions 26 and/or 28 may employ a pattern of continuously decreasing dimension to gradually narrow the transition region to achieve length L_{g}, rather than employing the step down pattern that narrows the pattern in discrete steps.

In the embodiments described above with respect to FIGS. 2A and 2B, adjustments were made to a photomask pattern 20, which was described as a pattern for a phase shift mask. However, photomask pattern 20 is not limited to a pattern for a phase shift mask, but could be any suitable type of photomask pattern, such as a conventional binary mask pattern that does not employ phase shifts, an attenuating mask pattern or a trim mask pattern.

Embodiments directed to adjustments for a trim mask pattern will now be discussed. As is well known in the art, both trim and phase masks are often used in double exposure methods. Critical features are generally imaged using a phase shift mask, and the non-critical and trim features are imaged in a second exposure using a trim mask. In regions where integrated circuit patterns are formed with a phase mask, such as the case of patterning integrated circuit feature 22 in the FIG. 2 embodiment, the trim mask may comprise one or more trim wings. Trim wings are patterns on the trim mask that protect the regions patterned by the phase mask from being imaged during the trim mask exposure.

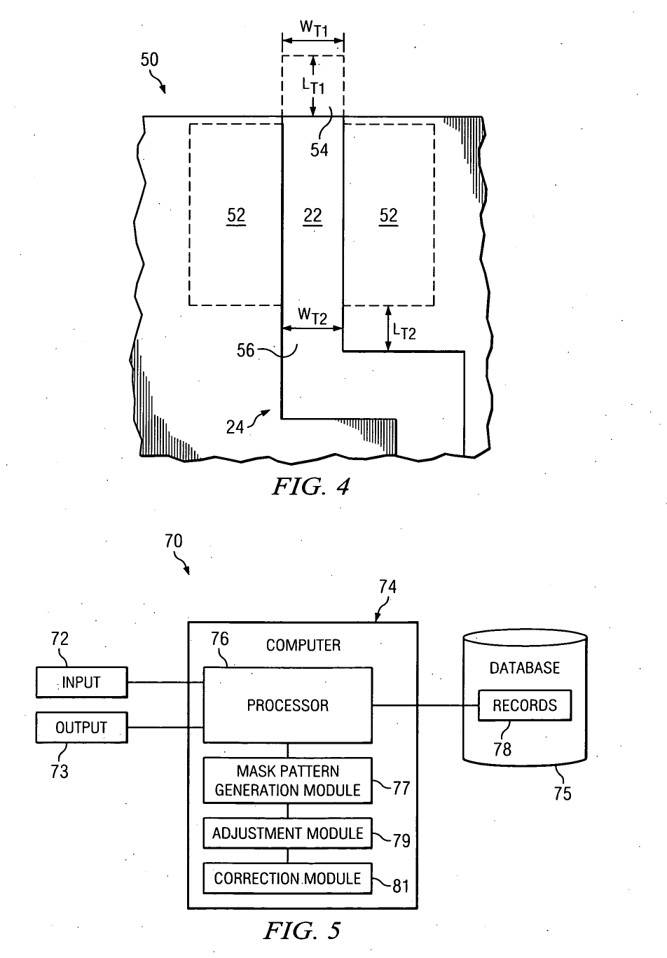

FIG. 4 illustrates one embodiment of a trim pattern 50 for patterning device 24 illustrated in the embodiment of FIG. 2A. Trim pattern 50 comprises trim wings 52, which represent an opaque region of the trim mask that, in conjunction with opaque region 24 (corresponding to device 24 in FIG. 2A), aid in protecting the integrated circuit feature 22 from being exposed to light during the trim mask exposure. Trim pattern 50 may also comprise a trim wing 54, having a length, Lₜ₁, and a width, Wₜ₁, that extends past the end of device 24 for protecting the end regions of the gate from exposure.

In some embodiments, the lack of control of segment positioning during correction for proximity effects, discussed above with reference to FIG. 3A, may be addressed by adjusting the dimensions of trim pattern 50, either in addition to, or in place of, adjusting the photomask pattern 20 of FIG. 2A. As discussed above in the description of FIG. 3A, segments A and A′ are positioned a relatively large distance apart in order to account for optical effects near the transition regions, such as the need to create a large enough dark region to begin the photoresist pattern at the transition region 26. Since in double exposure techniques, the total light intensity proximate to transition region 26 in FIG. 3A includes the combined light from both the trim and phase mask exposures, the trim mask pattern may be altered so as to effect the positioning of segments of photomask patterns 20 and 40 during the optical proximity correction process.

For example, in some embodiments, the light intensity proximate to transition region 26 may be decreased by increasing length Lₜ₁ of trim mask region 54. In other embodiments, the light intensity proximate to transition region 26 may be decreased by increasing width, Wₜ₁, of trim mask region 54. In yet other embodiments, both Lₜ₁ and Wₜ₁ may be increased to decrease the light intensity proximate to transition region 26.

Decreasing the light intensity proximate to transition region 26 can effectively reduce the size of the dark space required in the phase mask exposure to pattern the photoresist, thereby decreasing the distance between repositioned segments A and A′ in the optical proximity correction process of FIG. 3A. Because the dark space between segments A and A′ is decreased above segments B and B′, adjusting the trim mask to decrease light intensity can provide a more gradual decrease in the relative distances between the repositioned A, A′ segments and the repositioned B, B′ segments. This may result in improved control of the spatial response during the proximity correction process and allow patterning of the target dimension within design tolerances, or at least avoid forming portions of the integrated circuit feature to be shorter than design tolerances permit.

Similarly, the light intensity proximate transition region 28 of FIG. 2A may be adjusted by adjusting the length, Lₜ₂ and/or the width, Wₜ₂, of trim mask region 56 of FIG. 4. This can result in a more gradual positioning of the segments for patterning device 24 proximate transition region 28, and may result in improved control of the spatial response during the proximity correction process.

In some embodiments, adjusting the trim pattern to account for transition region effects may be sufficient to avoid the lack of control of the spatial response, as described with respect to FIG. 3A above, and to allow the target dimension of integrated circuit feature 22 to be formed with desired design tolerances, without the need to adjust the photomask pattern 20 to account for transition region effects. In yet other embodiments, the trim mask may be adjusted in addition to altering the photomask pattern 20, as described above in the embodiment of FIG. 2B. Adjusting the trim mask may allow a more gradual step down pattern in photomask pattern 20, so that dimensions for L₁ and/or L₂ in the FIG. 2B embodiment are reduced compared to the dimensions for L₁ and/or L₂ necessary to achieve the same effect if no adjustments to the trim mask were made.

Other embodiments of the present application are directed to photomasks comprising patterns formed by any of the methods of the present application, as discussed above. For example, one such embodiment is directed to an integrated circuit feature having a target dimension that is designed to be formed within a desired tolerance range. The photomask is made by a method comprising providing a first pattern that comprises a region for patterning the target dimension and a transition region, the transition region comprising a change in dimension to achieve the target dimension. The transition region of the first pattern is adjusted to form a second pattern that provides a more gradual change in dimension to achieve the target dimension than the transition region of the first pattern. The second pattern is corrected for proximity effects to form the photomask pattern, as described above. The resulting corrected pattern may comprise, for example, a step down pattern, such as the one illustrated in FIG. 3B, where the target dimension is a gate length.

Other embodiments of the present application are directed to methods of forming an integrated circuit employing the photomasks made by the processes of the present application. In embodiments, integrated circuits can be formed by applying a photoresist to a wafer and then exposing the photoresist to radiation through a photomask made by any of the methods described above. The exposed photoresist is then developed by methods well known in the art. An etching process can then be carried out using the photoresist to pattern the wafer, as is also well known in the art.

Yet other embodiments of the present application are directed to integrated circuits formed using the photomasks of the present application. In embodiments, integrated circuits can be patterned by applying a photoresist to a wafer and then exposing the photoresist to radiation through a photomask made by any of the methods described above. The exposed photoresist is then developed by methods well known in the art. An etching process can then be carried out using the photoresist to pattern the wafer, as is also well known in the art.

In embodiments, integrated circuit devices formed using the photomasks of the present application can comprise features corresponding to the adjustments made to the transition regions of the photomask patterns, as described above. In one embodiment where the photomask pattern is adjusted to account for transition region effects, the integrated circuit features patterned using the photomask may comprise a more gradual change in dimension in device regions corresponding to the transition regions of the photomask patterns than if the adjustments to the transition regions had not been made, so as to reduce or avoid the overshoot and/or undershoot problems discussed above. For example, the device may have gate end regions corresponding to transition regions 26 and/or 28 of FIG. 2B where the device pattern decreases in dimension to gradually narrow the device regions corresponding to the transition regions to achieve the desired gate length L_{g} of feature 22, similarly as shown in FIG. 2B, although the decrease may not necessarily occur in discrete steps in the device, but may occur more as a continuous decrease in dimension, as would be understood by one of ordinary skill in the art. In this manner, undershooting the target gate length may be reduced or avoided in the device, similarly as described above.

FIG. 5 illustrates a system 70 for forming a photomask pattern, according to embodiments of the present application. System 70 includes an input device 72 and an output device 73 coupled to a computer 74, which is in turn coupled to a database 75. Input device 72 may comprise, for example, a keyboard, a mouse, or any other device suitable for transmitting data to computer 74. Output device 73 may comprise, for example, a display, a printer, or any other device suitable for outputting data received from computer 74.

Computer 74 may comprise a personal computer, workstation, network computer, wireless computer, or one or more microprocessors within these or other devices, or any other suitable processing device. Computer 74 may include a processor 76, one or more photomask pattern generation modules 77, an adjustment module 79 for determining pattern adjustments, and a correction module 81.

The above modules, including the one or more photomask pattern generation modules 77, adjustment module 79, and correction module 81, can exist as software that comprises program instructions in source code, object code, executable code or other formats; program instructions implemented in firmware; or hardware description language (HDL) files. Any of the above can be embodied on a computer readable medium, which include storage devices and signals, in compressed or uncompressed form. Exemplary computer readable storage devices include conventional computer system-RAM (random access memory), ROM (read-only memory), EPROM (erasable, programmable ROM), EEPROM (electrically erasable, programmable ROM), and magnetic or optical disks or tapes.

Processor 76 controls the flow of data between input device 72, output device 73, database 75, photomask pattern generation module 77, adjustment module 79 and/or correction module 81. Photomask pattern generation module 77 may receive descriptions of integrated circuit device features from database 75 and generate a first pattern as described above. Adjustment module 79 may determine pattern adjustments to the first pattern for forming a second pattern, as also described herein above, and generate output describing the pattern adjustments. The output may be in any desirable form, including in the form of computer readable data that can be accessed by processor 76. Correction module 81 may receive descriptions of photomask patterns generated, including any adjustments from adjustment module 79, and generate corrected photomask patterns therefrom, as described above.

Database 75 may comprise any suitable system for storing data. Database 75 may store records 78 that comprise data associated with the integrated circuit device features. Records 78 may also comprise data associated with recognizing and/or defining photomask patterns to be adjusted by adjustment module 79, as well as parameters used for adjusting photomask patterns.

For the purposes of this specification and appended claims, unless otherwise indicated, all numbers expressing quantities, percentages or proportions, and other numerical values used in the specification and claims, are to be understood as being modified in all instances by the term “about.” Accordingly, unless indicated to the contrary, the numerical parameters set forth in the following specification and attached claims are approximations that can vary depending upon the desired properties sought to be obtained by the present disclosure. At the very least, and not as an attempt to limit the application of the doctrine of equivalents to the scope of the claims, each numerical parameter should at least be construed in light of the number of reported significant digits and by applying ordinary rounding techniques.

It is noted that, as used in this specification and the appended claims, the singular forms “a,” “an,” and “the,” include plural referents unless expressly and unequivocally limited to one referent. Thus, for example, reference to “an acid” includes two or more different acids. As used herein, the term “include” and its grammatical variants are intended to be non-limiting, such that recitation of items in a list is not to the exclusion of other like items that can be substituted or added to the listed items.

While particular embodiments have been described, alternatives, modifications, variations, improvements, and substantial equivalents that are or can be presently unforeseen can arise to applicants or others skilled in the art. Accordingly, the appended claims as filed and as they can be amended are intended to embrace all such alternatives, modifications variations, improvements, and substantial equivalents.

What is claimed is:

1. A method of forming a photomask pattern for writing a photomask, the method comprising:
providing a first pattern for forming an integrated circuit feature;
adjusting the first pattern to form a second pattern that accounts for transition region effects in the first pattern; and
correcting the second pattern for proximity effects to form the photomask pattern.

2. The method of claim 1, wherein the integrated circuit feature has a target dimension that is designed to be formed within a desired tolerance range, and wherein the first pattern comprises a region for patterning the target dimension and a transition region, the transition region comprising a change in dimension to achieve the target dimension.

3. The method of claim 2, wherein adjusting the first pattern comprises adjusting the transition region so that the second pattern is capable of being corrected for proximity effects in a manner that avoids forming portions of the integrated circuit feature to be shorter than design tolerances permit.

4. The method of claim 3, wherein the transition region in the first pattern comprises a second target dimension that is different from the first target dimension, the change in dimension being the transition from the second target dimension to the first target dimension.

5. The method of claim 3, wherein the transition region is proximate to an end of the first pattern, the change in dimension being the transition from the target dimension to the end of the pattern.

6. The method of claim 3, wherein adjusting the first pattern to form the second pattern comprises altering the transition region to achieve the target dimension, the change in dimension in the second pattern being more gradual than in the first pattern.

7. The method of claim 6, wherein adjusting the first pattern comprises altering the transition region to include a step down pattern comprising one or more increasingly narrow pattern regions to achieve the target dimension.

8. The method of claim 3, wherein the integrated circuit feature is a transistor gate and the target dimension is a gate length.

9. The method of claim 8, wherein the first pattern further comprises an interconnect pattern region having a second target dimension of a second length that is different from the gate length, the change in dimension being the transition from the second length to the gate length, and further wherein adjusting the first pattern comprises altering the transition region to include a step down pattern comprising one or more increasingly narrow pattern regions to achieve the gate length.

10. The method of claim 8, wherein the transistor gate is proximate to an end of the first pattern, the change in dimension being the transition from the gate length to the end of the pattern, and further wherein adjusting the first pattern comprises altering the transition region to include a step down pattern comprising one or more increasingly narrow pattern regions to achieve the gate length.

11. The method of claim 3, wherein the photomask pattern is a phase pattern comprising two or more phase blocks positioned to define the target dimension, and further wherein adjusting the first pattern comprises adjusting the two or more phase blocks.

12. The method of claim 11, wherein correcting the second pattern for proximity effects comprises:
dividing the phase blocks into a plurality of segments to define the target dimension; and
repositioning the plurality of segments to account for proximity effects,
wherein the change in dimension to achieve the target dimension is capable of causing an oscillatory repositioning of the segments that can result in the target dimension being outside the design tolerance range, and
wherein the adjusting of the first pattern dampens the oscillatory repositioning of the segments sufficiently to avoid forming portions of the integrated circuit feature to be shorter than design tolerances permit.

13. The method of claim 1, wherein the first pattern is a trim pattern, and further wherein adjusting the first pattern comprises adjusting the dimensions of the trim pattern.

14. A photomask comprising a pattern formed by the method of claim 1.

15. A system for generating a photomask pattern, the system comprising:
a database operable to store data describing an integrated circuit feature having a target dimension; and
a module coupled to the database, wherein the module comprises a set of instructions in computer readable form that are operable to:
determine pattern adjustments to a first pattern for forming the integrated circuit feature to account for transition region effects in the first pattern; and
generate output representing the pattern adjustments.

16. The system of claim 15, wherein the pattern adjustments to the first pattern can be used to form a second pattern capable of being corrected for proximity effects in a manner that avoids forming portions of the integrated circuit feature to be shorter than design tolerances permit.

17. The system of claim 16, wherein the first pattern comprises a region for patterning the target dimension and a transition region, the transition region comprising a change in dimension to achieve the target dimension.

18. The system of claim 17, wherein the integrated circuit feature is a gate region of a transistor and the target dimension is a preselected gate length.

19. The system of claim 18, wherein the transition region in the first pattern comprises a transition from the gate length to a second length, and further wherein the module is operable to adjust the transition from the gate length to the second length so that the transition is more gradual in the second pattern than in the first pattern.

20. The system of claim 18, wherein the transition region in the first pattern comprises a transition from the gate length to an end of the first pattern, and further wherein the module is operable to adjust the transition from the gate length to the end of the first pattern so that the transition is more gradual than in the first pattern.

21. A method of forming a photomask pattern for an integrated circuit feature having a gate length that is designed to be formed within a desired tolerance range, the method comprising:
providing a first pattern comprising a region for patterning the gate length and a transition region, the transition region comprising a change in dimension to achieve the gate length;
adjusting the transition region of the first pattern to form a second pattern that provides a more gradual change in dimension to achieve the gate length than the transition region of the first pattern; and
correcting the second pattern for proximity effects to form the photomask pattern.

22. A photomask comprising a pattern for forming an integrated circuit feature having a target dimension that is designed to be formed within a desired tolerance range, the photomask made by a method comprising:
providing a first pattern comprising a region for patterning the target dimension and a transition region, the transition region comprising a change in dimension to achieve the target dimension;
adjusting the transition region of the first pattern to form a second pattern that provides a more gradual change in dimension to achieve the target dimension than the transition region of the first pattern; and
correcting the second pattern for proximity effects to form the photomask pattern.

23. The photomask of claim 22, wherein adjusting the first pattern results in the transition region comprising a step down pattern of one or more increasingly narrow pattern regions to achieve the target dimension.

24. A method of forming an integrated circuit device, the method comprising:
applying a photoresist to a wafer;
exposing the photoresist to radiation through a photomask;
developing the photoresist; and
etching the wafer to form the integrated circuit device,
wherein the photomask is made by the method of claim 22.

25. An integrated circuit device formed by the process of claim 24.
